(19) United States
(12) Patent Application Publication
(10) Pub. No.: US 2025/0293102 A1
(43) Pub. Date: Sep. 18, 2025

(54) STRUCTURAL ENCLOSURE FOR PROTECTION AGAINST FOREIGN OBJECT DEBRIS

(71) Applicant: Raytheon Company, Waltham, MA (US)

(72) Inventors: Kevin A. Miyamoto, Camarillo, CA (US); Andrew J. Bristol, Brentwood, CA (US); Keith R. Burrell, Rancho Palos Verdes, CA (US); Charles Chu, Temple City, CA (US)

(21) Appl. No.: 18/307,101

(22) Filed: Apr. 26, 2023

(51) Int. Cl. H01L 23/04; H01L 23/10

(52) U.S. Cl. CPC H01L 23/041; H01L 23/10

(57) ABSTRACT

A system includes a substrate and an electrical component mounted to the substrate. The electrical component includes multiple conductive connectors physically and electrically connecting the electrical component to the substrate. The system also includes a structural enclosure positioned around lateral edges of the electrical component and mounted to the substrate. The structural enclosure includes raised walls extending away from the substrate and surrounding the electrical component. The raised walls are configured to block foreign object debris from contacting the conductive connectors. The electrical component may further include a semiconductor die and a lid, the lid may be in thermal contact with the semiconductor die, and the structural enclosure may be attached to the lid. The structural enclosure may further include multiple projections extending from the raised walls, and the lid may be attached to the projections of the structural enclosure.

### GOVERNMENT RIGHTS

This invention was made with government support under contract number FA8810-18-C-0005 (PO 4103856333) awarded by the United States Department of Defense. The government has certain rights in the invention.

### TECHNICAL FIELD

This disclosure relates generally to electronic systems. More specifically, this disclosure relates to a structural enclosure for protection against foreign object debris.

### BACKGROUND

Electronic devices routinely include processors or other electrical components that are mounted to printed circuit boards. The mounting of a processor or other electrical component to a printed circuit board may be accomplished in various ways. In some cases, one possible mounting approach involves the use of a column grid array, which includes multiple (possibly numerous) electrical conductors. The electrical conductors can be used to form electrical connections between a processor or other electrical component and electrical traces or other conductive structures on a printed circuit board.

### SUMMARY

This disclosure relates to a structural enclosure for protection against foreign object debris.

In a first embodiment, a system includes a substrate and an electrical component mounted to the substrate. The electrical component includes multiple conductive connectors physically and electrically connecting the electrical component to the substrate. The system also includes a structural enclosure positioned around lateral edges of the electrical component and mounted to the substrate. The structural enclosure includes raised walls extending away from the substrate and surrounding the electrical component. The raised walls are configured to block foreign object debris from contacting the conductive connectors.

In a second embodiment, a method includes obtaining an electrical component mounted to a substrate, where the electrical component includes multiple conductive connectors physically and electrically connecting the electrical component to the substrate. The method also includes attaching a structural enclosure to the substrate such that the structural enclosure is positioned around lateral edges of the electrical component. The structural enclosure includes raised walls extending away from the substrate and surrounding the electrical component. The raised walls are configured to block foreign object debris from contacting the conductive connectors.

In a third embodiment, an apparatus includes a structural enclosure configured to be mounted to a substrate and positioned around lateral edges of an electrical component mounted to the substrate. The structural enclosure includes raised walls configured to surround the electrical component. The raised walls are configured to block foreign object debris from contacting conductive connectors of the electrical component.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1 illustrates an example system that includes a structural enclosure for protection against foreign object debris according to this disclosure;

FIGS. 2 and 3 illustrate example details of a system that includes a structural enclosure for protection against foreign object debris according to this disclosure; and

FIG. 4 illustrates an example method for using a structural enclosure for protection against foreign object debris according to this disclosure.

### DETAILED DESCRIPTION

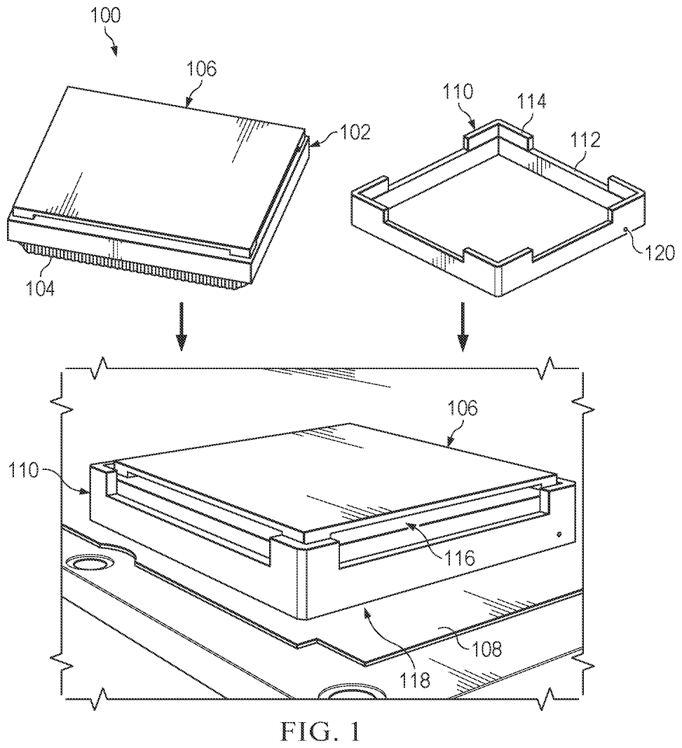

FIGS. 1 through 4, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, electronic devices routinely include processors or other electrical components that are mounted to printed circuit boards. The mounting of a processor or other electrical component to a printed circuit board may be accomplished in various ways. In some cases, one possible mounting approach involves the use of a column grid array, which includes multiple (possibly numerous) electrical conductors. The electrical conductors can be used to form electrical connections between a processor or other electrical component and electrical traces or other conductive structures on a printed circuit board.

Column grid arrays are useful in a number of applications, such as space-based applications or other applications in which large temperature changes occur. This is because differences in coefficients of thermal expansion (CTE) can cause different devices to expand and contract at different rates when subjected to the same temperature changes. This can create large amounts of stresses, but column grid arrays are often able to accommodate large CTE mismatches over large and repeated thermal cycles. As a result, column grid arrays can be used to help obtain high performance and high reliability.

Unfortunately, column grid arrays may provide additional failure modes that are not present (or that are present to a lesser extent) in other mechanisms for electrically coupling processors or other electrical components to printed circuit boards. For example, column grid arrays tend to be taller than some other mechanisms for electrically coupling processors or other electrical components to printed circuit boards, such as ball grid arrays. Also, columns along the outer edges of the column grid arrays are typically exposed after coupling of the processors or other electrical components to the printed circuit boards. As a result, it is possible for random objects or materials (often referred to as foreign object debris) to inadvertently contact portions of column grid arrays. If the foreign object debris is electrically conductive and the processors or other electrical components are powered on, the foreign object debris may create short-circuits, cause damage to the processors or other electrical components, or create other problems with the processors or other electrical components.

While it might be possible to build up edge bonding that is used to couple a processor or other electrical component to a printed circuit board so that the edge bonding itself provides protection for a column grid array, this tends to be a very process-intensive approach. As a result, this approach can take a prolonged period of time to implement and can be more expensive, and the results may or may not actually work due to the larger heights of the column grid arrays. In other words, a column grid array may be too tall for built-up edge bonding to be effective. Similarly, underfilling is a technique that involves inserting material into a space between a processor or other electrical component and a printed circuit board, but underfilling often cannot be used with column grid arrays due to their heights.

Moreover, some processors or other electrical components may include lids attached to the processors or other electrical components, and these lids are often attached using thermal interface materials. Thermal interface materials can be relatively weak, which raises the risk of the lids separating from the processors or other electrical components when subjected to shear loads. If a lid is used to facilitate cooling of a processor or other electrical component, the loss of the lid can inhibit the ability to cool the processor or other electrical component, which might render the processor or other electrical component inoperable.

This disclosure provides a structural enclosure for protection against foreign object debris. As described in more detail below, a structural enclosure can be sized to fit around a processor or other electrical component, and the structural enclosure can be mounted to a printed circuit board or other substrate to which the processor or other electrical component is mounted. The structural enclosure can be fabricated from one or more electrically conductive materials or non-electrically conductive materials, such as one or more plastics or metals. However the structural enclosure is fabricated, the structural enclosure acts as a barrier between a column grid array or other conductive connectors of the processor or other electrical component and foreign object debris. As a result, the structural enclosure can be used to protect the column grid array or other conductive connectors or to protect the processor or other electrical component from damage or other problems caused by foreign object debris. In some cases, the structural enclosure may be installed on a printed circuit board or other substrate after a processor or other electrical component is installed on the printed circuit board or other substrate. Also, in some cases, epoxy or other material(s) may be used to fill one or more gaps around the structural enclosure.

The structural enclosure may optionally be used to receive or hold a lid or other component in place above the processor or other electrical component. For instance, the lid may be used to facilitate cooling of the processor or other electrical component, and the structural enclosure may be used to help hold the lid in place (even in the presence of large shear loads). In some cases, for example, the structural enclosure may include projections extending above walls of the structural enclosure, and the projections may be used to help hold the lid in place. The structural enclosure may also optionally be formed of at least one radiation-hardened or radiation-tolerant material, such as through appropriate material selection for the structural enclosure. This can help to provide radiation protection for the processor or other electrical component, which may itself represent a radiation-hardened or radiation-tolerant component.

Depending on the implementation, the structural enclosure may require little if any additional area on a printed circuit board or other substrate beyond the area that is already available. This can be a useful or desirable feature in some applications, such as when size and weight are important factors. Also, the structural enclosure may be fabricated from one or more materials that are pre-qualified or pre-approved for use in certain applications or environments like in space-based or other applications, and the structural enclosure may be fabricated using common techniques like three-dimensional (3D) printing or other techniques. As a result, there may be little or no need to undergo qualification of new materials and new machining or other processes in order to fabricate and use the structural enclosure. Further, the structural enclosure can provide protection against foreign object debris without affecting the integrity of a column grid array or other conductive connectors. In addition, if a lid or other structure is used with the processor or other electrical component, the structural enclosure can help to hold the lid or other structure in place, even if the lid or other structure is coupled to the processor or other electrical component using a weak thermal interface material. This can be useful or desirable in applications in which an overall system is subjected to shear loads, such as shear loads due to vibrations, shock, large thermal cycles, or other causes.

FIG. 1 illustrates an example system 100 that includes a structural enclosure for protection against foreign object debris according to this disclosure. As shown in FIG. 1, the system 100 includes an electrical component 102, which in this example takes the form of a processor. The electrical component 102 may have any suitable form factor. For instance, in some cases, a processor used as the electrical component 102 may typically have a square or rectangular cross-section along a horizontal plane through the electrical component 102 and a rectangular cross-section along a vertical plane through the electrical component 102. Also, the size of the electrical component 102 may vary depending on the application. As a particular example, the electrical component 102 may represent a processor having a size of about 42 millimeters by about 42 millimeters. However, the electrical component 102 can have any suitable size, shape, and dimensions. Note that while the electrical component 102 is often described as representing a processor, any other suitable electrical component 102 may be used here.

The electrical component 102 includes an array or other collection of conductive connectors 104. The conductive connectors 104 enable electrical signals to be transported to and from the electrical component 102 during operation of the electrical component 102. For example, the conductive connectors 104 may be used to provide electrical power to the electrical component 102, such as electrical power from a battery, power adapter, solar cell, or other power source. The conductive connectors 104 may also be used to provide information to or receive information from the electrical component 102. The conductive connectors 104 may be formed from any suitable material(s), such as one or more metals like solder. The conductive connectors 104 may also have any suitable form, such as columns or other elongated forms. As a particular example, the conductive connectors 104 may be formed as non-collapsible solder columns. In some embodiments, the conductive connectors 104 may form a column grid array.

There may be any suitable number of conductive connectors 104 used with the electrical component 102, which can depend on (among other things) the size and capabilities of the electrical component 102. As a particular example, the electrical component 102 may have up to 1,700 conductive connectors 104 or even more in a column grid array or other array. In addition, each conductive connector 104 may have any suitable height. As a particular example, each conductive connector 104 may be about 2.2 millimeters tall. Due to their heights and the tight spacings between the conductive connectors 104, it is possible for the conductive connectors 104 to trap foreign object debris, which (if electrically conductive) could short-out key electrical functions of the electrical component 102, damage the electrical component 102, or create other problems with the electrical component 102.

An additional component, such as a lid 106, may form a part of or be used with the electrical component 102. The lid 106 may be used to cover the electrical component 102, such as to help provide protection for the electrical component 102. The lid 106 may also be used for other or additional purposes. For example, the lid 106 may be used to help facilitate cooling of the electrical component 102, such as by removing thermal energy from the electrical component 102 and allowing the thermal energy to be removed from the lid 106 (possibly via a heat strap or other conductive thermal transfer mechanism or via radiation or convection). The lid 106 may also or alternatively be formed using at least one radiation-hardened or radiation-tolerant material, which can help to provide radiation protection for the electrical component 102 (which itself may be radiation-hardened or radiation-tolerant).

As shown in FIG. 1, the electrical component 102 is mounted to an underlying substrate 108, which in this example takes the form of a printed circuit board. For example, the conductive connectors 104 of the electrical component 102 may be placed on the surface of the underlying substrate 108 or pass through holes of the underlying substrate 108, and solder or other material(s) may be used to secure the conductive connectors 104 to the underlying substrate 108. This can help to couple electrical traces or other conductive structures of the underlying substrate 108 to the conductive connectors 104, thereby providing electrical pathways between the electrical component 102 and the conductive structures of the underlying substrate 108. The underlying substrate 108 represents any suitable structure on or to which at least the electrical component 102 can be mounted. Note that while the underlying substrate 108 is often described as representing a printed circuit board, any other suitable substrate 108 may be used here.

A structural enclosure 110 is used with the electrical component 102 in order to protect the conductive connectors 104 and other portions of the electrical component 102 from foreign object debris. As can be seen in FIG. 1, the structural enclosure 110 is sized to fit around the electrical component 102 and blocks access to much or all of the conductive connectors 104. In some cases, however, the structural enclosure 110 may not actually contact the electrical component 102 and can remain spaced apart from the electrical component 102. The structural enclosure 110 can also be mounted to the underlying substrate 108 in order to hold the structural enclosure 110 in place. The structural enclosure 110 can be mounted to the underlying substrate 108 in any suitable manner, such as via edge bonding using appropriate material(s) like epoxy. In some embodiments, the structural enclosure 110 can be mounted to the underlying substrate 108 after the electrical component 102 has been mounted to the underlying substrate 108. Among other things, this may allow for functional verification of a circuit card assembly or other assembly that includes the electrical component 102 and the underlying substrate 108 with or without the structural enclosure 110.

In this example, the structural enclosure 110 includes raised walls 112 and optional projections 114 extending from the tops of the raised walls 112. The raised walls 112 represent portions of the structural enclosure 110 that are attached along their bottom edges to the underlying substrate 108 and that extend upward around at least the conductive connectors 104 of the electrical component 102 (and possibly other portions of the electrical component 102). In this particular implementation, the structural enclosure 110 includes four raised walls 112 forming a square. However, the number of raised walls 112 and the shape formed by the raised walls 112 can vary, such as depending on the size and shape of the electrical component 102 being protected.

The projections 114 extending from the tops of the raised walls 112 can be used to help secure the lid 106 in place on the electrical component 102. For example, the lid 106 may be placed on the projections 114 or in the space between the projections 114, and the lid 106 can be secured to the projections 114. The lid 106 can be secured to the projections 114 in any suitable manner, such as via the use of an adhesive staking. This allows the lid 106 to remain in place even if the overall system 100 is subjected to shear loads like those caused by vibrations, shock, or large thermal cycles. Maintaining the lid 106 in place may be extremely important in some embodiments, such as when the lid 106 is used for thermal management purposes (and where loss of the lid 106 can inhibit the ability to cool the electrical component 102, which might render the electrical component 102 inoperable). In this particular example, each of the projections 114 is formed by two surfaces at a right angle, where two of the raised walls 112 are extended upward in certain locations to form each projection 114. Note, however, that each projection 114 may have any other suitable form. Also note that the projections 114 may be omitted, such as when the lid 106 is not used, when the lid 106 can be securely coupled to the electrical component 102 with suitable strength to resist shear loads, or when the lid 106 can be attached to the raised walls 112 without the projections 114.

The structural enclosure 110 may be fabricated using any suitable material or materials. For example, in some embodiments, the structural enclosure 110 may be fabricated using one or more non-electrically conductive materials, such as one or more plastics like acrylonitrile butadiene styrene (ABS) plastic. In other embodiments, the structural enclosure 110 may be fabricated using one or more electrically conductive materials, such as one or more metals. Moreover, the structural enclosure 110 may or may not be fabricated using one or more radiation-hardened or radiation-tolerant materials. In addition, in some cases, the structural enclosure 110 may be fabricated using one or more materials that are pre-qualified or pre-approved for use in at least one specified application or environment, such as when the structural enclosure 110 is fabricated using one or more materials that are pre-qualified for use in space-based applications. One specific example of such a pre-qualified material for use in space-based applications is ABS-ESD7 fused deposition modeling (FDM) thermoplastic available from STRATASYS, LTD.

The structural enclosure 110 may also be fabricated in any suitable manner. For example, in some embodiments, the structural enclosure 110 may be fabricated using 3D printing or other additive manufacturing technique. In other embodiments, the structural enclosure 110 may be fabricated using computer numerical controlled (CNC) machining or other subtractive manufacturing technique. In still other embodiments, the structural enclosure 110 may be fabricated using injection molding. However the structural enclosure 110 is fabricated, in some cases, the structural enclosure 110 may have a form that closely matches the form of the electrical component 102 being protected (at least to within a specified tolerance), which allows the structural enclosure 110 to fit closely around the electrical component 102. Also, in some cases, there may be no need to undergo qualification of new materials and new machining or other processes in order to fabricate and use the structural enclosure 110.

As can be seen in FIG. 1, the structural enclosure 110 is positioned around and provides protection along the lateral sides of the electrical component 102. Among other things, the structural enclosure 110 helps to prevent ingress of foreign object debris towards the conductive connectors 104, thereby helping to reduce the likelihood of a short-circuit, damage, or other problems occurring as a result of the foreign object debris. Note that, due to manufacturing processes and the presence of the projections 114, there may still be one or more gaps 116 or 118 along the top or bottom edges of the structural enclosure 110 through which smaller foreign object debris may pass. If that is a concern, these gaps 116 or 118 may be at least partially filled as described below. Also, one or more small holes or other openings 120 may be provided in the structural enclosure 110. The opening(s) 120 may be small enough to prevent passage of foreign object debris while providing pressure relief for the space within the structural enclosure 110. Pressure relief may be useful, for example, when the gaps 116 and 118 are sealed as described below.

In some cases, the structural enclosure 110 here may require little if any additional area on the printed circuit board or other underlying substrate 108 beyond the area that is already available. Among other reasons, this may be due to the existence of a standard assembly “keep out” zone around the electrical component 102, which refers to a zone around the electrical component 102 in which other electrically-active components may not be positioned. The ability to use existing space on the underlying substrate 108 may be useful or desirable in various applications, such as space-based applications or other applications in which reducing or minimizing size and weight is needed or desired. Moreover, the structural enclosure 110 can provide protection against foreign object debris without affecting the integrity of the conductive connectors 104. This is because the structural enclosure 110 sits around the electrical component 102 and does not require the buildup of any materials around the conductive connectors 104 themselves.

Note that while space-based applications have been mentioned specifically above as one type of example usage of the structural enclosure 110, the structural enclosure 110 may be used in any suitable applications in any suitable environments. This can include various terrestrial, seaborne, airborne, and space-based applications in which at least one processor or other electrical component 102 is mounted to at least one printed circuit board or other underlying substrate 108. The structural enclosure 110 may also be used with any suitable electrical components 102, such as high-performance processors or other high-performance electronics.

Although FIG. 1 illustrates one example of a system 100 that includes a structural enclosure 110 for protection against foreign object debris, various changes may be made to FIG. 1. For example, various components shown in FIG. 1 may be combined, further subdivided, replicated, omitted, or rearranged and additional components may be added according to particular needs. Thus, the system 100 may include any suitable number of each component shown in FIG. 1, and those components may be arranged in any suitable manner. Also, the size, shape, and dimensions of each component shown in FIG. 1 are examples only and can vary as needed or desired. In addition, while FIG. 1 illustrates one example environment in which one or more structural enclosures 110 may be used to provide protection against foreign object debris, the structural enclosures 110 may be used in any other suitable environments.

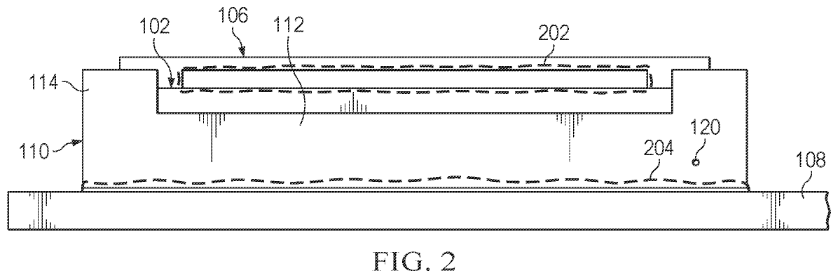

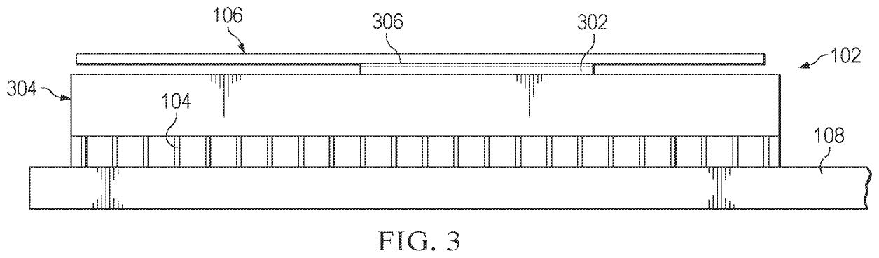

FIGS. 2 and 3 illustrate example details of the system 100 that includes the structural enclosure 110 for protection against foreign object debris according to this disclosure. As shown in FIG. 2, the one or more gaps 116 or 118 along the top or bottom edges of the structural enclosure 110 may optionally be sealed or otherwise at least partially blocked. For example, a material 202 may be deposited along each gap 116 in order to reduce or prevent the ability of foreign object debris to pass through that gap 116. Similarly, a material 204 may be deposited along each gap 118 in order to reduce or prevent the ability of foreign object debris to pass through that gap 118. Any suitable material(s) 202, 204 may be used here, such as epoxy or edge bonding material. Note, however, that use of either or both materials 202 and 204 may not be needed in some embodiments.

As shown in FIG. 3, a cross-section of an example electrical component 102 is shown. The electrical component 102 in this example includes a semiconductor die 302 positioned on top of a ceramic or other interconnect substrate 304. The conductive connectors 104 pass through or are electrically coupled to connectors that pass through the interconnect substrate 304 in order to electrically couple the semiconductor die 302 to electrical traces or other conductive structures on the underlying substrate 108. It can be seen here that the conductive connectors 104 are relatively long and packed closely together, which raises risks of foreign object debris causing short-circuits, damage, or other problems with the electrical component 102. Among other things, the structural enclosure 110 can help to block foreign object debris from contacting the conductive connectors 104. For instance, the raised walls 112 of the structural enclosure 110 can be at least as tall as (as typically taller than) the conductive connectors 104.

Also as shown in FIG. 3, the lid 106 can be positioned over the semiconductor die 302, and a thermal interface material 306 can be positioned between and contact the lid 106 and the semiconductor die 302. The thermal interface material 306 helps to facilitate more effective transport of thermal energy from the semiconductor die 302 to the lid 106, which can help to cool the semiconductor die 302 during operation of the electrical component 102. However, as noted above, the thermal interface material 306 may be weak in some cases, which may allow the lid 106 to move or actually separate from the semiconductor die 302 due to shear loads. Among other things, the structural enclosure 110 can help to hold the lid 106 in place so that the lid 106 remains in thermal contact with the semiconductor die 302.

Although FIGS. 2 and 3 illustrate examples of details of the system 100 that includes the structural enclosure 110 for protection against foreign object debris, various changes may be made to FIGS. 2 and 3. For example, the specific gaps 116 and 118 that exist can vary based on the design of the structural enclosure 110 and the design of the electrical component 102. Also, as noted above, there may be no need to fill one or both of the gaps 116 and 118 with the material(s) 202, 204. Further, the electrical component 102 may have any other suitable form and is not limited to the specific design shown in FIG. 3. In addition, while the thermal interface material 306 may be weak in some embodiments, other embodiments may use a thermal interface material 306 that is more resistant to shear loads. This is one reason why the use of the projections 114 is optional, since there may be some instances in which there is little or no need to physically attach the structural enclosure 110 to the lid 106.

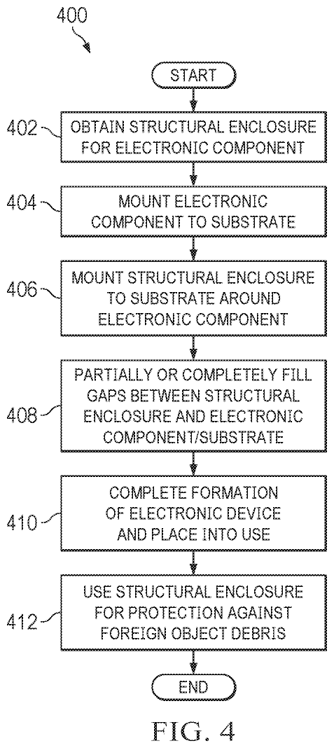

FIG. 4 illustrates an example method 400 for using a structural enclosure for protection against foreign object debris according to this disclosure. For ease of explanation, the method 400 is described as involving the use of the structural enclosure 110 with the electrical component 102 within the system 100 shown in FIG. 1. However, the structural enclosure 110 may be used with any other suitable electrical component(s) and in any other suitable system(s).

As shown in FIG. 4, a structural enclosure for an electrical component is obtained at step 402. This may include, for example, fabricating or otherwise obtaining a structural enclosure 110 that is designed for use with at least one specified electrical component 102. As noted above, in some cases, the structural enclosure 110 can have a size, shape, and dimensions that allow the structural enclosure 110 to surround and protect the specified electrical component 102. Often times, the structural enclosure 110 will closely follow the outer edges or lateral sides of the electrical component 102, at least to within some desired tolerance.

The electrical component is mounted to a substrate at step 404. This may include, for example, mounting the electrical component 102 to a printed circuit board or other underlying substrate 108 using the conductive connectors 104 of the electrical component 102. In some embodiments, for instance, the conductive connectors 104 may be surface-mounted to the printed circuit board or other underlying substrate 108 in order to secure the electrical component 102 to the underlying substrate 108. The structural enclosure is mounted to the substrate at step 406. This may include, for example, mounting the structural enclosure 110 to the printed circuit board or other underlying substrate 108 so that the structural enclosure 110 surrounds the electrical component 102. In some embodiments, for instance, the structural enclosure 110 may be mounted to the printed circuit board or other underlying substrate 108 using edge bonding or other technique.

One or more gaps between the structural enclosure and the electrical component or between the structural enclosure and the substrate may be partially or completely filled at step 408. This may include, for example, depositing material 202 partially or completely filling one, some, or all gaps 116 between the structural enclosure 110 and the electrical component 102. This may also or alternatively include depositing material 204 partially or completely filling one, some, or all gaps 118 between the structural enclosure 110 and the underlying substrate 108. Note, however, that this step is optional if gap filling is not needed or desired.

Formation of an electronic device may be completed and the device may be placed into use at step 410, and the structural enclosure can be used to provide protection against foreign object debris at step 412. This may include, for example, performing integration or other operations to incorporate the electrical component 102 and the underlying substrate 108 into a larger device or system. This may also include the structural enclosure 110 limiting or preventing foreign object debris from contacting at least the conductive connectors 104 of the electrical component 102 during the subsequent integration or use operations involving the electrical component 102.

Although FIG. 4 illustrates one example of a method 400 for using a structural enclosure for protection against foreign object debris, various changes may be made to FIG. 4. For example, while shown as a series of steps, various steps in FIG. 4 may overlap, occur in parallel, occur in a different order, or occur any number of times (including zero times).

The following describes example embodiments of this disclosure that implement or relate to a structural enclosure for protection against foreign object debris. However, other embodiments may be used in accordance with the teachings of this disclosure.

In a first embodiment, a system includes a substrate and an electrical component mounted to the substrate. The electrical component includes multiple conductive connectors physically and electrically connecting the electrical component to the substrate. The system also includes a structural enclosure positioned around lateral edges of the electrical component and mounted to the substrate. The structural enclosure includes raised walls extending away from the substrate and surrounding the electrical component. The raised walls are configured to block foreign object debris from contacting the conductive connectors.

In a second embodiment, a method includes obtaining an electrical component mounted to a substrate, where the electrical component includes multiple conductive connectors physically and electrically connecting the electrical component to the substrate. The method also includes attaching a structural enclosure to the substrate such that the structural enclosure is positioned around lateral edges of the electrical component. The structural enclosure includes raised walls extending away from the substrate and surrounding the electrical component. The raised walls are configured to block foreign object debris from contacting the conductive connectors.

In a third embodiment, an apparatus includes a structural enclosure configured to be mounted to a substrate and positioned around lateral edges of an electrical component mounted to the substrate. The structural enclosure includes raised walls configured to surround the electrical component. The raised walls are configured to block foreign object debris from contacting conductive connectors of the electrical component.

Any single one or any suitable combination of the following features may be used with the first, second, or third embodiment. The electrical component may include a semiconductor die and a lid, the lid may be in thermal contact with the semiconductor die, and the structural enclosure may be attached to the lid. The structural enclosure may include multiple projections extending from the raised walls, and the lid may be attached to the projections of the structural enclosure. The raised walls may be as tall as or taller than the conductive connectors. A material may at least partially fill one or more gaps between the structural enclosure and the electrical component. A material may at least partially fill one or more gaps between the structural enclosure and the substrate. The structural enclosure may include a 3D printed structure. The structural enclosure may remain spaced apart from the electrical component and may not contact the electrical component. The electrical component may include a processor. The conductive connectors may form a column grid array. The substrate may include a printed circuit board. The conductive connectors may be surface-mounted to a surface of the substrate, and the structural enclosure may be attached to the surface of the substrate.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A system comprising:
a substrate;
an electrical component mounted to the substrate, the electrical component comprising multiple conductive connectors physically and electrically connecting the electrical component to the substrate; and
a structural enclosure positioned around lateral edges of the electrical component and mounted to the substrate, the structural enclosure comprising raised walls extending away from the substrate and surrounding the electrical component, the raised walls configured to block foreign object debris from contacting the conductive connectors.

2. The system of claim 1, wherein:
the electrical component further comprises a semiconductor die and a lid, the lid in thermal contact with the semiconductor die; and
the structural enclosure is attached to the lid.

3. The system of claim 2, wherein:
the structural enclosure further comprises multiple projections extending from the raised walls; and
the lid is attached to the projections of the structural enclosure.

4. The system of claim 1, wherein the raised walls are as tall as or taller than the conductive connectors.

5. The system of claim 1, further comprising at least one of:
a material at least partially filling one or more gaps between the structural enclosure and the electrical component; and
a material at least partially filling one or more gaps between the structural enclosure and the substrate.

6. The system of claim 1, wherein the structural enclosure comprises a three-dimensional (3D) printed structure.

7. The system of claim 1, wherein the structural enclosure remains spaced apart from the electrical component and does not contact the electrical component.

8. The system of claim 1, wherein:
the electrical component comprises a processor;
the conductive connectors form a column grid array; and
the substrate comprises a printed circuit board.

9. The system of claim 1, wherein:
the conductive connectors are surface-mounted to a surface of the substrate; and
the structural enclosure is attached to the surface of the substrate.

10. A method comprising:
obtaining an electrical component mounted to a substrate, the electrical component comprising multiple conductive connectors physically and electrically connecting the electrical component to the substrate; and
attaching a structural enclosure to the substrate such that the structural enclosure is positioned around lateral edges of the electrical component, the structural enclosure comprising raised walls extending away from the substrate and surrounding the electrical component, the raised walls configured to block foreign object debris from contacting the conductive connectors.

11. The method of claim 10, wherein:
the electrical component further comprises a semiconductor die and a lid, the lid in thermal contact with the semiconductor die; and
the method further comprises attaching the structural enclosure to the lid.

12. The method of claim 11, wherein:
the structural enclosure further comprises multiple projections extending from the raised walls; and
the lid is attached to the projections of the structural enclosure.

13. The method of claim 10, wherein the raised walls are as tall as or taller than the conductive connectors.

14. The method of claim 10, further comprising at least one of:
using a material to at least partially fill one or more gaps between the structural enclosure and the electrical component; and
using a material to at least partially fill one or more gaps between the structural enclosure and the substrate.

15. The method of claim 10, wherein the structural enclosure comprises a three-dimensional (3D) printed structure.

16. The method of claim 10, wherein the structural enclosure remains spaced apart from the electrical component and does not contact the electrical component.

17. The method of claim 10, wherein:
the electrical component comprises a processor;
the conductive connectors form a column grid array; and
the substrate comprises a printed circuit board.

18. The method of claim 10, wherein:
the conductive connectors are surface-mounted to a surface of the substrate; and
the structural enclosure is attached to the surface of the substrate.

19. An apparatus comprising:
a structural enclosure configured to be mounted to a substrate and positioned around lateral edges of an electrical component mounted to the substrate;
wherein the structural enclosure comprises raised walls configured to surround the electrical component, the raised walls configured to block foreign object debris from contacting conductive connectors of the electrical component.

20. The apparatus of claim 19, further comprising:
multiple projections extending from the raised walls, the projections configured to be attached to a lid of the electrical component.
